(19) United States
(12) Patent Application Publication
(10) Pub. No.: US 2013/0133717 A1
(43) Pub. Date: May 30, 2013

(54) SOLAR CELL MODULE AND METHOD FOR MANUFACTURING THE SAME

(71) Applicant: Sanyo Electric Co., Ltd., Moriguchi City (JP)

(72) Inventors: Kenichi Maki, Osaka (JP); Satoshi Tohada, Kobe-shi (JP); Yoshiyuki Kudoh, Osaka (JP); Haruhisa Hashimoto, Osaka (JP)

(73) Assignee: Sanyo Electric Co., Ltd., Moriguchi City (JP)

(21) Appl. No.: 13/727,546

(22) Filed: Dec. 26, 2012

Related U.S. Application Data
(63) Continuation of application No. PCT/JP2011/064933, filed on Jun. 29, 2011.

(30) Foreign Application Priority Data
Jun. 30, 2010 (JP) 2010-149693

(51) Int. Cl. H01L 31/05; H01L 31/18

(52) U.S. Cl. CPC H01L 31/0508; H01L 31/18; H01L 31/0512
USPC 136/244; 156/292

(57) ABSTRACT

A solar cell module includes a plurality of solar cells including a photoelectric conversion unit, and an electrode which is formed on the surface of the photoelectric conversion unit; a wiring member that electrically connects the plurality of solar cells; and a resin adhesive that adheres the solar cells and the wiring member. Non-contiguous regions of the resin adhesive are present between the wiring member and the solar cells.

### CROSS REFERENCE TO RELATED APPLICATIONS

This application is a continuation application of International Application No. PCT/JP2011/064933, filed on Jun. 29, 2011, entitled “SOLAR CELL MODULE AND METHOD FOR MANUFACTURING THE SAME”, which claims priority based on Article 8 of Patent Cooperation Treaty from prior Japanese Patent Applications No. 2010-149693, filed on Jun. 30, 2010, the entire contents of which are incorporated herein by reference.

### BACKGROUND OF THE INVENTION

1. Field of the Invention

This disclosure relates to a solar cell module and a method for manufacturing the same.

2. Description of Related Art

Solar cell modules have attracted greater attention in recent years as an energy source that is friendly to the environment.

In general, a solar cell module includes a plurality of solar cells. The plurality of solar cells are electrically connected in series or in parallel by a wiring material.

Conventionally, solder has been widely used for the adhesion between the solar cell and the wiring material. However, in order to bond the solar cell and the wiring material by using solder, it is necessary to melt solder. Therefore, the solar cell becomes hot in the bonding process. As a result, there is a possibility that the solar cell is damaged, or deformed.

In view of this issue, the adhesion between the solar cell and the wiring material using a conductive resin adhesive has been studied in recent years (for example, see Document 1.)

When an adhesive resin such as a conductive resin adhesive is used for bonding the solar cell and the wiring material, the temperature can be kept low upon bonding, as opposed to using a solder for bonding. Therefore, damages or deformations etc. of the solar cell in the bonding process of the wiring material can be prevented.
Document 1: Japanese Patent Application Publication No. 2009-295940

### SUMMARY OF THE INVENTION

Meanwhile, the standard of durability for solar cells to bear the repeated temperature changes, which is required for a solar cell module, has become higher in recent years.

An object of an embodiment of the invention is to improve durability against repeated changes in temperature in a solar cell module, in which a solar cell and a wiring material are bonded with a resin adhesive.

An aspect of the invention includes a solar cell module that includes a plurality of solar cells, a wiring material, and a resin adhesive. Each of the plurality of solar cells includes a photoelectric conversion unit and electrodes. The electrodes are formed on a surface of the photoelectric conversion unit. The plurality of solar cells are electrically connected by the wiring material. The solar cell and the wiring are bonded by an resin adhesive. A non-contiguous adhesive resin region is present between the wiring material and the solar cell.

In a solar cell module according to the embodiment, the non-contiguous region is present preferably adjacent to the electrodes.

Another aspect of the invention includes a method of manufacturing a solar cell module that includes a plurality of solar cells having a photoelectric conversion unit and electrodes formed on a surface of the photoelectric conversion unit, a wiring material that electrically connects the plurality of solar cells, and an adhesive resin bonding the electrodes of the solar cell and the wiring material. The method for manufacturing a solar cell module according to the embodiment includes pressing the solar cell and the wiring material together in a state where a resin adhesive material that is thinner than the height of the electrodes is placed between the solar cell and the wiring material thereby electrically connecting the electrode and the wiring material, as well as bonding the solar cell and the wiring material by curing the resin sheet.

According to the aspects of embodiments, the durability against repeated changes in temperature is further improved in a solar cell module including a solar cell and a wiring material bonded with a resin adhesive.

### BRIEF DESCRIPTION OF THE DRAWINGS

FIG. 1 is a schematic cross-sectional view of a solar cell module according to an embodiment.

FIG. 2 is a schematic plan view seen from a light-receiving surface side of the solar cell.

FIG. 3 is a schematic cross-sectional view taken along line III-III of FIG. 2.

FIG. 4 is a schematic cross-sectional view for explaining a step for connecting a wiring material according to the embodiment.

FIG. 5 is a schematic cross-sectional view for explaining a step for connecting wiring material according to a first modified example.

FIG. 6 is a schematic plan view seen from the light receiving surface side of the solar cell in a second modified example.

FIG. 7 is a schematic plan view seen from the light receiving surface side of the solar cell in a third modified example.

FIG. 8 is a graph showing the results of temperature cycle tests in each of Example 1 and Comparative Example 1.

### DETAILED DESCRIPTION OF EMBODIMENTS

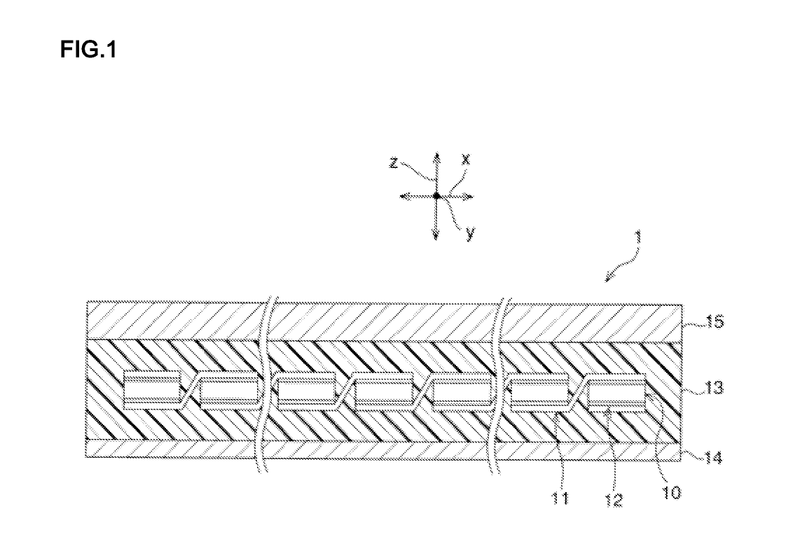

The following describes preferred embodiments referring to solar cell module 1 shown in FIG. 1 as an example. Note that solar cell module 1 is a mere example, and the solar cell module according to the embodiment is not particularly limited to solar cell module 1.

In the drawings referred to in embodiments and modified examples, the same reference sign denote members having substantially the same function. The drawings referred to in embodiments and the like are schematic and ratios of dimensions and the like of an object in the drawings might be different from actual ratios of dimensions and the like. Moreover, the drawings also include objects having different ratios of dimensions. Therefore, specific ratios of dimensions and the like should be determined in consideration of the following description.

### (Schematic Structure of Solar Cell Module 1)

FIG. 1 is a schematic cross-sectional view of solar cell module 1 according to an embodiment.

The solar cell module 1 includes a plurality of solar cells 10 that are arranged along array direction x. The plurality of solar cells 10 are electrically connected by wiring material 11. Specifically, a plurality of solar cells 10 are electrically connected in series or in parallel by electrical connection between neighboring solar cells 10 by wiring material 11.

First and second protection members 14 and 15 are disposed in a light-receiving surface side and a back side of the plurality of solar cells 10. Sealing material 13 is provided between first protection member 14 and second protection member 15. The plurality of solar cells 10 are sealed by this sealing material 13.

Materials for sealing material 13, and first and second protection members 14, 15 are not particularly limited. For example, sealing material 13 may be formed by a resin having a light-transmitting property such as ethylene-vinyl acetate copolymer (EVA) and polyvinyl butyral (PVB).

First and second protection members 14, 15 may be formed, for example, with glass, resin or the like. Also, for example, one of first and second protection members 14, 15 may be formed by a resin film in which a metal foil such as aluminum foil is interposed. In this embodiment, first protection member 14 is disposed on the back side of solar cell 10, and is formed by a resin film in which the metal foil such as aluminum foil is interposed. Second protection member 15 is disposed on a light-receiving surface side of solar cell 10, and is formed by glass or transparent resin.

### (The Structure of Solar Cell 10)

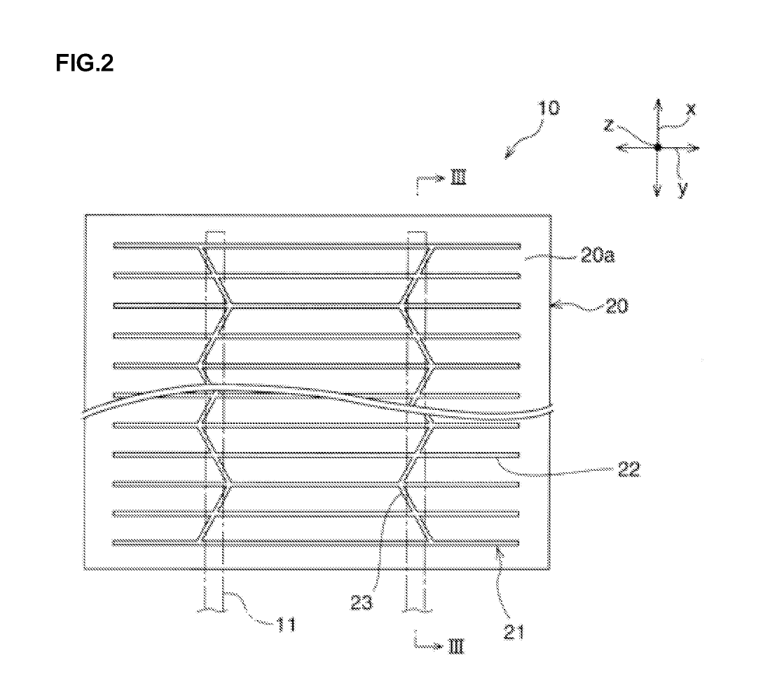

FIG. 2 is a schematic plan view seen from the light-receiving surface side of the solar cell. Note that solar cell 10 described herein is a mere example. In the embodiment, the type and structure of a solar cell is not limited to this configuration in any way.

Moreover, in this embodiment, one main surface of solar cell 10 is a light-receiving surface and the other main surface is a back surface. However, in the embodiment, both main surfaces may be the light-receiving surface of the solar cell. In that case, each of first and second protection members 14, 15 preferably have a light-transmitting property.

### (Photoelectric Conversion Unit 20)

As shown in FIG. 2 solar cell 10 includes photoelectric conversion unit 20. Photoelectric conversion unit 20 generates carriers (electrons and holes) upon receiving light.

Photoelectric conversion unit 20 includes semiconductor material having a semiconductor junction such as a HIT junction (registered trademark), a p-n junction, or a p-i-n junction. Examples of semiconductor materials are crystalline semiconductors such as monocrystalline silicon and polycrystalline silicon, thin film semiconductors such as amorphous silicon, and compound semiconductors such as GaAs.

### (Electrode 21)

Electrode 21 is formed on light-receiving surface 20a of photoelectric conversion unit 20. Although not shown in the figure, electrode 21 is formed on the back surface of photoelectric conversion unit 20. As shown in FIG. 2, electrode 21 includes a plurality of finger electrodes 22, and a plurality of bus bars 23. Note that in this embodiment, the plurality of finger electrodes 22 and the plurality of bus bar 23 are integrally formed.

Each of the plurality of finger electrodes 22 extends parallel to each other in direction y, which is perpendicular to array direction x. The plurality of finger electrodes 22 are arranged parallel to each other along arrangement direction x.

Bus bar 23 is formed in a staggered array along arrangement direction x. This bus bar 23 is electrically connected to the plurality of finger electrodes 22.

### (Electrical Connection of Solar Cell 10 by Wiring Material 11)

As shown in FIG. 1, solar cells 10 that are disposed adjacent to each other are electrically connected by wiring material 11. More specifically, one portion of wiring material 11 is electrically connected to electrode 21 of light-receiving surface side 20a of solar cell 10, and the other portion of wiring material 11 is electrically connected to electrode 21 on the back side of neighboring solar cell 10 that is adjacent to this solar cell 10. Thus neighboring solar cells 10 are electrically connected by wiring material 11.

Wiring material 11 is not particularly limited as long as it is conductive. For example, wiring material 11 may include a wiring material main body and a coating layer that covers the wiring material main body. The wiring material main body can be formed by, for example, Cu. The coating layer may be formed, for example, by metal such as Ag and an alloy such as solder.

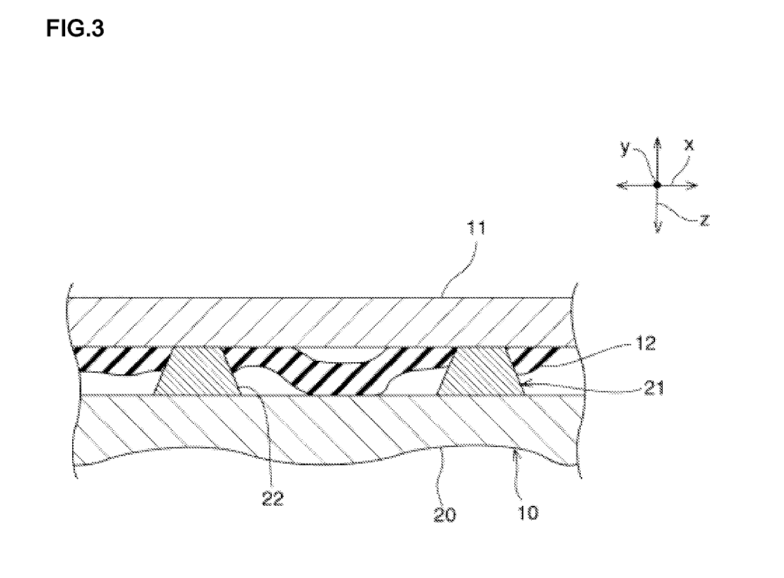

As shown in FIGS. 1 and 3, wiring material 11 and solar cell 10 are bonded by resin adhesive 12. In the present embodiment, specifically, solar cell 10 and wiring material 11 are bonded by the resin adhesive 12 in a state where electrode 21 of solar cell 10 and wiring material 11 are in direct contact. Thus, in the present embodiment, electrode 21 and wiring material 11 are electrically connected by making direct contact with electrode 21 and wiring material 11. Resin adhesive 12 is formed to bridge a back surface of wiring material 11 and a side surface of electrode 21 thereby bonding each other. Furthermore, resin adhesive 12 is formed partially to reach a surface of photoelectric conversion unit 20 from the back surface of wiring material 11 via the side surface of electrode 21, thereby bonding these wiring material 11, electrode 21, and photoelectric conversion unit 20.

Resin adhesive 12 includes a resin having an adhesive property. Specific examples of the adhesive resin are, for instance, an epoxy resin, an acrylic resin, a polyimide resin, a phenol resin, an urethane resin, a silicone resin, and a mixture of at least two of these resins and a copolymer.

Resin adhesive 12 may have either an electrical conductivity or an insulating property. Examples of resin adhesive 12 having an electrical conductivity are, for instance, anisotropic conductive resins and the like including the above mentioned resins that contain conductive particles. Examples of conductive particles are metals such as nickel, copper, silver, aluminum, tin, and gold, as well as alloy particles including one or more of these metals, or insulating particles that are treated with a conductive coating process including a metal coating process or an alloy coating process.

Further, in the case where resin adhesive 12 has the insulating properties, it is also possible to form insulating adhesive 12 with the above-mentioned resins. Also, insulating adhesive 12 may be formed by the above-mentioned resins that contain insulating particles such as silica.

As shown in FIG. 3, in this embodiment, there is a region between wiring member 11 and solar cell 10 that is not filled with resin adhesive 12. That is, in between wiring material 11 and solar cell 10, there is a non-contiguous region where resin adhesive 12 is not located continuously from wiring material 11 to solar cell 10 in a direction opposing to wiring material 11 and solar cell 10. Further, this non-contiguous region is also present in portions adjacent to electrode 21.

### (Method for Manufacturing Solar Cell Module 1)

Next, a method for manufacturing solar cell module 1 is described in detail.

First, photoelectric conversion unit 20 is prepared. Note that photoelectric conversion unit 20 can be manufactured by conventional methods.

Next, solar cell 10 is completed by forming electrode 21 on each of light receiving surface 20a and the back surface of photoelectric conversion unit 20. The method of forming electrode 21 is not particularly limited. Electrode 21 may be formed, for example, by printing the conductive paste by a screen printing method.

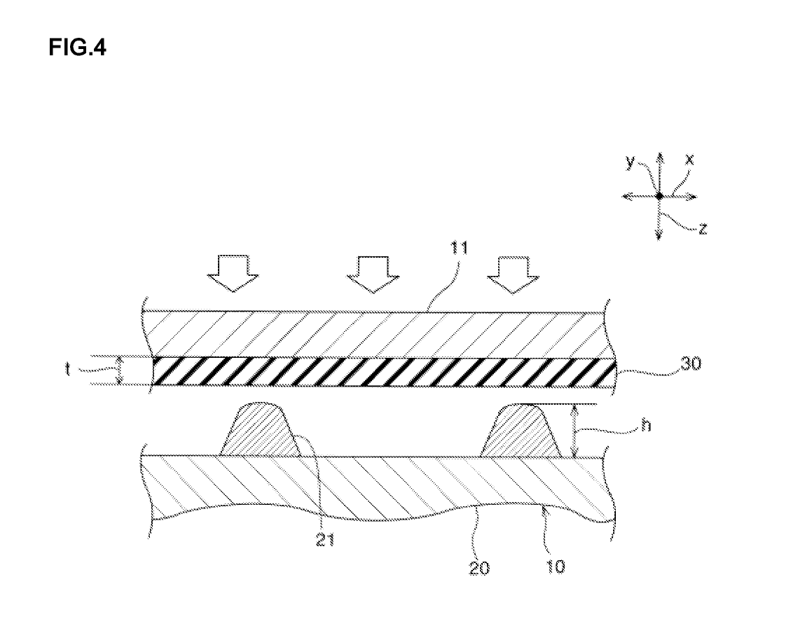

Next, a plurality of solar cells 10 prepared as described above are electrically connected by wiring material 11. Specifically, as shown in FIG. 4, while resin sheet 30 is disposed between solar cell 10 and wiring material 11, solar cell 10 and wiring material 11 are pressed together until wiring material 11 and electrode 21 are in direct contact. Then, resin sheet 30 is cured in this state, thereby bonding solar cell 10 and wiring material 11. The resultant cured product of resin sheet 30 becomes resin adhesive 12.

Here, in this embodiment, resin sheet 30 having thickness t that is smaller than height h of electrode 21 is used. Therefore, as shown in FIG. 3, the non-contiguous region is formed.

Note that resin sheet 30 can be formed by, for example, energy-ray-curable resins such as a thermosetting resin and a photo-curable resin. In this case, resin sheet 30 can be cured by energy ray curing. Furthermore, resin sheet 30 can also be formed by, for example, a thermoplastic resin, in this case, resin sheet 30 is temporarily softened by heating, and then cured by cooling.

By repeating the adhesion between solar cell 10 and wiring material 11 as described above, the plurality of solar cells 10 are electrically connected.

Next, a resin sheet such as an EVA sheet is disposed on second protection member 15. The plurality of solar cells 10 that are connected by wiring material 11 are disposed on the resin sheet. A resin sheet such as EVA sheet is disposed thereon, and first protection member 14 is further disposed thereon. After these are tentatively pressure-bonded by heat and pressure under the atmosphere of a reduced pressure, the resin sheet is cured by heating again. Solar cell module 1 is produced through the steps described above.

Note that a terminal box and a metal frame and the like may be installed if necessary.

As described above, in the area between wiring material 11 and solar cell 10 in this embodiment, the non-contiguous region where resin adhesive 12 is not continuously located from wiring material 11 to solar cell 10 is provided in opposing direction z. Namely, wiring material 11 is bonded to solar cell 10 partially by resin adhesive 12, rather than wiring material and solar cell are entirely adhered by resin adhesive 12. Therefore, the effects of thermal stress caused by repeated temperature change due to differences in thermal expansion coefficients between wiring member 11 and solar cell 10 during routine use can be mitigated. Accordingly, problems such as a separation of wiring material 11 can be prevented. As a result, the durability of solar cell module 1 can be improved.

In this embodiment, the non-contiguous region where resin adhesive 12 is not continuously located from wiring material 11 to solar cell 10 is provided in opposing direction z. By providing the non-contiguous region, the separation of the wiring material from the solar cell due to repeated changes in temperature can be prevented. Accordingly, a high durability can be achieved.

The volume percent of the non-contiguous region occupied in the area between wiring material 11 and solar cell 10 is preferably not less than approximately 20% of the area. However, if the volume percent of the non-contiguous region to the region between wiring material 11 and solar cell 10 becomes too great, the bond strength between wiring material 11 and electrode 21 may become too weak. Thus, the volume percent of the non-contiguous region occupied in the area between wiring material 11 and solar cell 10 is preferably not more than 80%.

### First Modified Example

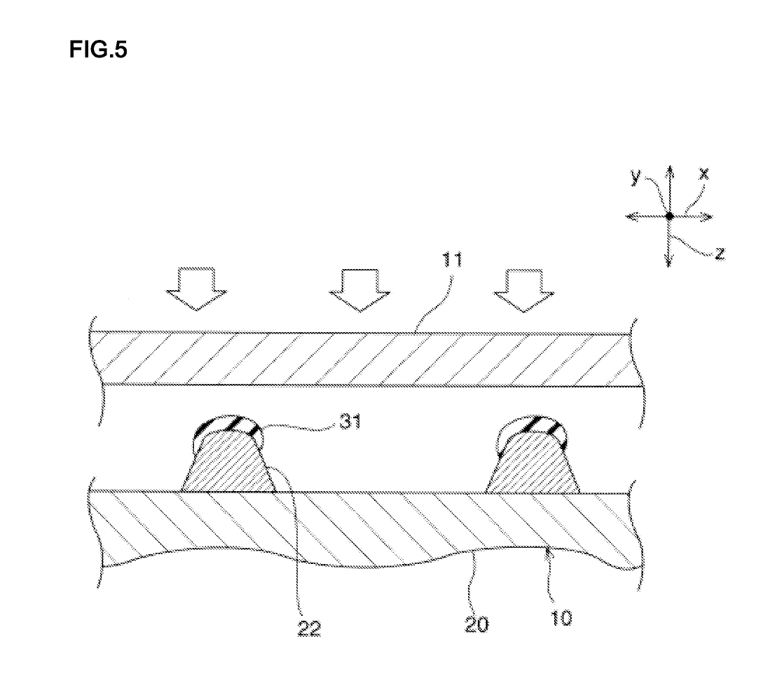

FIG. 5 is a schematic cross-sectional view for explaining a step for connecting wiring material according to a first modified example of the embodiment.

In the above embodiment, an example of forming a non-contiguous region is described by using thin resin sheet 30 having thickness t that is smaller than height h of electrode 21. However, in the embodiment, the method for forming the non-contiguous region is not limited to this method.

For example, as shown in FIG. 5, resin adhesive 12 can be formed by resin 31 by applying resin 31 to the top portion of electrode 21. Even in this case, the non-contiguous region can be suitably formed.

### Second and Third Modified Examples

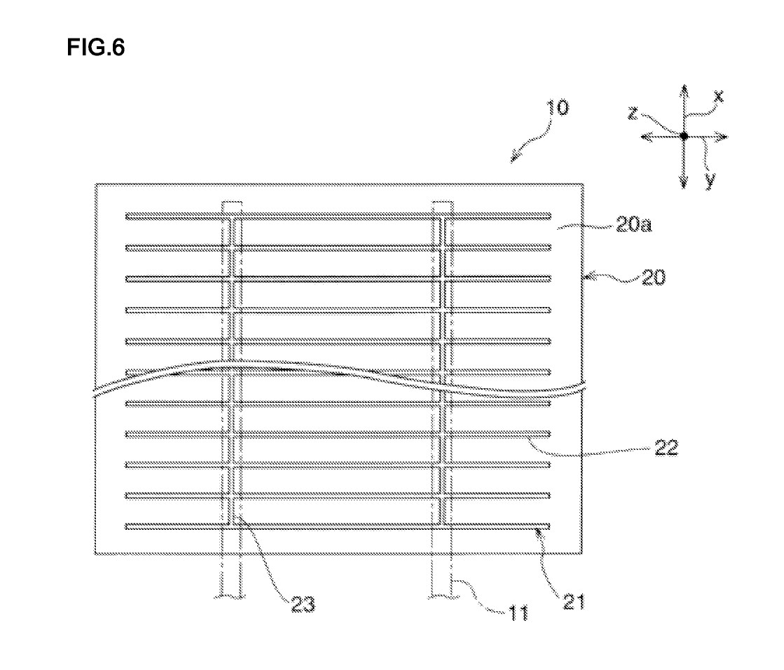

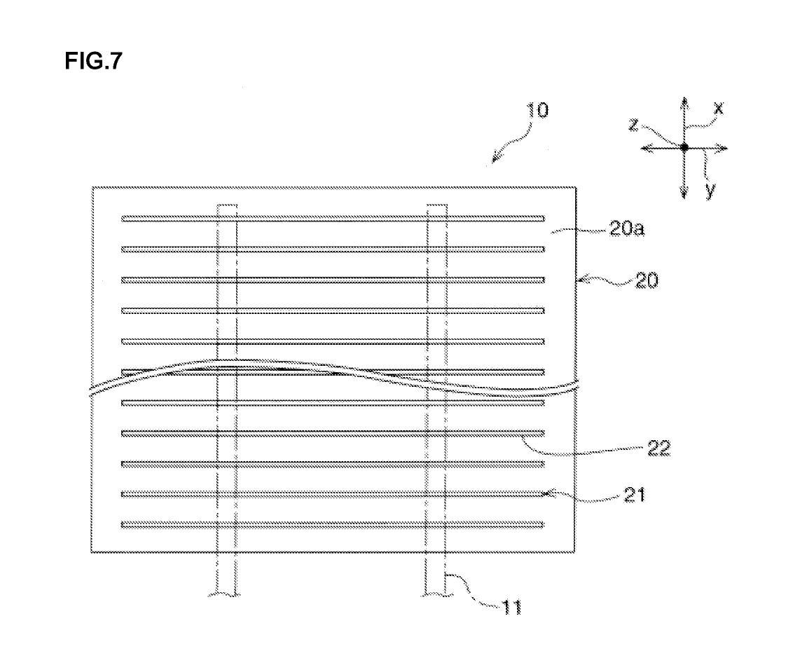

FIG. 6 is a schematic plan view seen from the light receiving surface side of the solar cell in a second modified example. FIG. 7 is a schematic plan view seen from the light receiving surface side of the solar cell in a third modified example.

In the above embodiment, an example in which electrode 21 includes the plurality of bus bar formed in a staggered manner and the plurality of finger electrodes 22 is described. However, in the embodiment, the configuration of the electrode is not limited to this configuration.

As shown in FIG. 6, for example, electrode 21 may include the plurality of bus bar 23 formed in straight lines and the plurality of finger electrodes 22.

As shown in FIG. 7, for example, electrode 21 may be formed only by the plurality of finger electrodes 22, without providing bus bars.

Hereinafter, the embodiment will be described in more detail based on specific example, however, the embodiment is not limited to the following examples.

### Example 1 and Comparative Example 1

In Example 1, three solar cell modules having the same configuration as the above embodiment are prepared in accordance with the method described in the above embodiment, where the ratio of the thickness t of resin sheet 30 to height h of electrode 21 (t/h) is approximately 0.8.

Meanwhile, in Comparative Example 1, three solar cell modules are produced in the same manner as Example 1 except that the ratio of thickness t of the resin sheet to height h of electrode (t/h) is approximately 1.2.

As a result of observing the cross-section of a solar cell module produced in each of Example 1 and Comparative Example 1 with an electronic microscope, formation of a non-contiguous region as described in the above embodiment is confirmed in Example 1. In contrast, in Comparative Example 1, the non-contiguous region is either not formed or a very little amount of the non-contiguous region is formed if any, and it is confirmed that the area between the solar cell and wiring material is essentially filled with the resin.

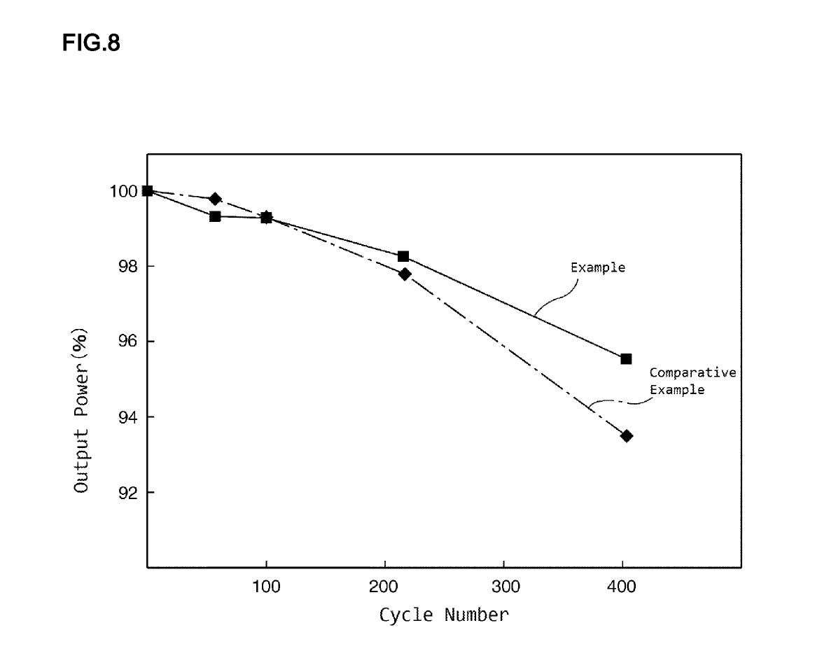

Next, the temperature cycle test is conducted using each of the three solar cell modules prepared in each of Example 1 and Comparative Example 1. In the temperature cycle test, 400 cycles of the test are carried out, in which one cycle constitutes a change of temperature from a high temperature (90° C.) to a low temperature (−40° C.) or from a low temperature to a high temperature. Then, measurements for the output power are taken after 0 cycles, 50 cycles, 100 cycles, 200 cycles and 400 cycles, respectively. Then, an average output power of three samples is calculated in each of Example 1 and Comparative Example 1. The results are shown in FIG. 8. Note that the output power shown in FIG. 8 is a normalized value in which an output power before conducting each of the temperature cycle tests is set as 100.

As shown in the results in FIG. 8, the output power reduction due to the repeated temperature change is smaller in Example 1 in which a non-contiguous region is formed than in Comparative Example 1 in which a non-contiguous region is not formed.

1. A solar cell module comprising:
a plurality of solar cells that includes a photoelectric conversion unit and an electrode formed on a surface of the photoelectric conversion unit;
a wiring material that electrically connects the plurality of solar cells; and
a resin adhesive that adheres the solar cell and the wiring material, wherein
a non-contiguous adhesive resin region is present in an area between the wiring material and the solar cell.

2. The solar cell module according to claim 1, wherein the non-contiguous region is present in a direction opposing to the wiring material and the solar cell.

3. The solar cell module according to claim 1, wherein the non-contiguous regions is present adjacent to the electrode.

4. The solar cell module according to claim 1, wherein a volume percent of the non-contiguous region that occupies an area between the wiring material and the solar cell is no less than 20% and no more than 80%.

5. A method for manufacturing a solar cell module comprising a plurality of solar cells that include a photoelectric conversion unit and an electrode formed on a surface of the photoelectric conversion unit,
a wiring material that electrically connects the plurality of solar cells, and
a resin adhesive that adheres the wiring material and the electrode of the solar cell,
the method comprising:
electrically connecting the electrode and the wiring material by pressing the solar cell and the wiring material together while a resin adhesive material having a thinner thickness than a height of the electrode is disposed in between the solar cell and the wiring material; and
curing the resin adhesive material thereby adhere the solar cell and the wiring material.

6. The method for manufacturing the solar cell module according to claim 5 comprising:
adhering the solar cell and the wiring material in a manner that the non-contiguous region is present between the wiring material and the solar cell.

7. A method for manufacturing a solar cell module including a plurality of solar cells that includes a photoelectric conversion unit and an electrode formed on a surface of the photoelectric conversion unit,
a wiring material that electrically connects the plurality of solar cells, and
a resin adhesive that adheres the wiring material and the electrode of the solar cell,
the method comprising:
applying an adhesive material on a top portion of the electrode;
pressing the solar cell and the wiring material together in a state that the wiring material is disposed on the electrode whose top portion is coated with the resin adhesive material; and
curing the resin adhesive material thereby electrically connect the electrode and the wiring material, as well as adhere the solar cell and the wiring material.

8. The method for manufacturing the solar cell module according to claim 7 comprising:
adhering the solar cell and the wiring material in a manner that a non-contiguous region is present between the wiring material and the solar cell.

9. The solar cell module according to claim 2, wherein the non-contiguous regions is present adjacent to the electrode.

10. The solar cell module according to claim 2, wherein a volume percent of the non-contiguous region that occupies an area between the wiring material and the solar cell is no less than 20% and no more than 80%.

11. The solar cell module according to claim 3, wherein a volume percent of the non-contiguous region that occupies an area between the wiring material and the solar cell is no less than 20% and no more than 80%.

12. The solar cell module according to claim 1, wherein the adhesive resin includes an epoxy resin, an acrylic resin, a polyimide resin, a phenol resin, an urethane resin, a silicone resin, and a mixture of at least two of these resins and a copolymer.

13. The solar cell module according to claim 1, wherein the adhesive resin includes insulating particles.

14. The solar cell module according to claim 1, wherein the adhesive resin includes conductive particles.

15. The solar cell module according to claim 5, wherein the adhesive resin material includes a resin sheet.

16. The solar cell module according to claim 5, wherein the adhesive resin material includes energy-ray-curable resins.

17. The solar cell module according to claim 16, wherein the adhesive resin material includes a thermosetting resin.

18. The solar cell module according to claim 16, wherein the adhesive resin material includes a photo-curable resin.

19. The solar cell module according to claim 16, wherein the adhesive resin material includes a thermoplastic resin.
